(19) United States
(12) Patent Application Publication
(10) Pub. No.: US 2026/0276733 A1
(43) Pub. Date: Sep. 17, 2026

(54) POWER-ON DETECTION CIRCUIT

(71) Applicant: eMemory Technology Inc., Hsin-Chu (TW)

(72) Inventors: Zhe-Yi LIN, Hsinchu County (TW); Dung Le Tan Hoang, Hsinchu County (TW); Chien-Han WU, Hsinchu County (TW)

(21) Appl. No.: 19/562,870

(22) Filed: Mar. 11, 2026

Related U.S. Application Data
(60) Provisional application No. 63/771,080, filed on Mar. 13, 2025.

(51) Int. Cl. G01R 31/40; H03K 3/3565; H03K 19/0185

(52) U.S. Cl. CPC G01R 31/40; H03K 3/3565; H03K 19/018507

(57) ABSTRACT

A power-on detection circuit includes a pull-up circuit, a pull-down circuit, a Schmitt trigger, a level shifting circuit, a combinational logic circuit, and a glitch filter. The pull-up circuit and the pull-down circuit are connected to a first node. The pull-down circuit receives a first supply voltage. The Schmitt trigger is connected to the first node. The Schmitt trigger generates a Schmitt output signal. An enable terminal of the level shifting circuit receives the Schmitt output signal. A first input signal is converted into a first level-shifted signal by the level shifting circuit. The combinational logic circuit receives the first level-shifted signal and the Schmitt output signal and generates a first power detecting signal. The glitch filter receives the first power detecting signal and generates a second power detecting signal.

### CROSS REFERENCE TO RELATED APPLICATIONS

This application claims the benefit of US provisional application Serial No. 63/771,080, filed Mar. 13, 2025, the subject matters of which is incorporated herein by reference.

### FIELD OF THE INVENTION

The present invention relates to a power-on detection circuit, and more particularly to a power-on detection circuit applicable to two power domains.

### BACKGROUND OF THE INVENTION

During the power-up period or the normal power supply process of the internal circuitry of an IC chip, the power supply voltage may become unstable due to unpredictable external or internal factors. Generally, a power-on detection circuit is an electrical component used to detect whether the supply voltage in the IC chip is abnormal. For example, when the output signal of the power-on detection circuit is in a first logic level state, it means that the supply voltage is normal. When the output signal of the power-on detection circuit is in a second logic level state, it means that the supply voltage is abnormal.

In the conventional IC chip, the power-on detection circuit receives only a single supply voltage and determines whether the supply voltage is abnormal.

### SUMMARY OF THE INVENTION

An embodiment of the present invention provides a power-on detection circuit. The power-on detection circuit receives a first supply voltage in a first power domain and a second supply voltage in a second power domain. The power-on detection circuit includes a pull-up circuit, a pull-down circuit, a Schmitt trigger, a level shifting circuit and a combinational logic circuit. The pull-up circuit is connected between the second supply voltage and a first node. The pull-down circuit receives the first supply voltage. The pull-down circuit is connected between the first node and a ground voltage. The Schmitt trigger is connected to the first node. The Schmitt trigger generates a Schmitt output signal according to a voltage at the first node. The Schmitt trigger is configured to provide hysteresis between a high threshold voltage and a low threshold voltage. An enable terminal of the level shifting circuit receives the Schmitt output signal. A first input terminal of the level shifting circuit receives a first input signal. An output terminal of the level shifting circuit generates a first level-shifted signal at the second supply voltage when the first input signal is at the first supply voltage. The combinational logic circuit receives the first level-shifted signal and the Schmitt output signal. The combinational logic circuit generates a first power detecting signal in a predetermined logic level state when the Schmitt output signal and the first level-shifted signal are at the second supply voltage. The first input signal is a signal belonging to the first power domain. The voltage at the first node, the first level-shifted signal, the Schmitt output signal and the first power detecting signal are signals belonging to the second power domain.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit block illustrating the architecture of a power-on detection circuit according to a first embodiment of the present invention;

FIG. 2A is a schematic circuit diagram illustrating the detailed circuitry of the power-on detection circuit according to the first embodiment of the present invention;

FIG. 2B is a schematic timing waveform diagram illustrating associated signals of the power-on detection circuit according to the first embodiment of the present invention;

FIG. 3A is a schematic circuit diagram illustrating a variant example of the detailed circuitry of the power-on detection circuit according to the first embodiment of the present invention;

FIG. 3B is a schematic circuit diagram illustrating another example of the pull-up circuit used in the power-on detection circuit shown in FIG. 3A;

FIG. 4 is a schematic circuit block illustrating the architecture of a power-on detection circuit according to a second embodiment of the present invention;

FIG. 5A is a schematic circuit diagram illustrating a first example of the pull-up circuit used in the power-on detection circuit of the second embodiment;

FIG. 5B is a schematic circuit diagram illustrating a second example of the pull-up circuit used in the power-on detection circuit of the second embodiment;

FIG. 5C is a schematic circuit diagram illustrating a third example of the pull-up circuit used in the power-on detection circuit of the second embodiment;

FIG. 5D is a schematic circuit diagram illustrating a fourth example of the pull-up circuit used in the power-on detection circuit of the second embodiment;

FIG. 5E is a schematic circuit diagram illustrating a first example of the pull-down circuit used in the power-on detection circuit of the second embodiment;

FIG. 5F is a schematic circuit diagram illustrating a second example of the pull-down circuit used in the power-on detection circuit of the second embodiment;

FIG. 6 is a schematic circuit block illustrating the architecture of a power-on detection circuit according to a third embodiment of the present invention; and

FIG. 7 is a schematic circuit block illustrating the architecture of a power-on detection circuit according to a fourth embodiment of the present invention.

### DETAILED DESCRIPTION OF PREFERRED EMBODIMENTS

Generally, there are several different power domains in an IC chip. Different power domains are supplied by different supply voltages. Consequently, the circuits in different power domains may have different logic levels. For example, a supply voltage V_{DD2} is greater than a supply voltage V_{DD1}. In the V_{DD1} power domain, the supply voltage V_{DD1} is 1V, the logic high level is 1V, and the logic low level is the ground voltage (0V). In the V_{DD2} power domain, the supply voltage V_{DD2} is 2.5V, the logic high level is 2.5V, and the logic low level is the ground voltage (0V). Furthermore, the signal communication between circuits in different power domains requires a level shifter to convert the logic levels.

The present invention provides a power-on detection circuit. The power-on detection circuit receives the two supply voltages V_{DD1} and V_{DD2}. The supply voltage V_{DD1} belongs to the V_{DD1} power domain. The supply voltage V_{DD2} belongs to the V_{DD2} power domain. Furthermore, the power-on detection circuit is equipped with a level shifter to convert the signal in the V_{DD1} power domain into a signal in the V_{DD2} power domain. In other words, the power-on detection circuit of the present invention utilizes the circuitry in the V_{DD2} power domain to determine whether the supply voltage V_{DD1} in the V_{DD1}power domain is normal.

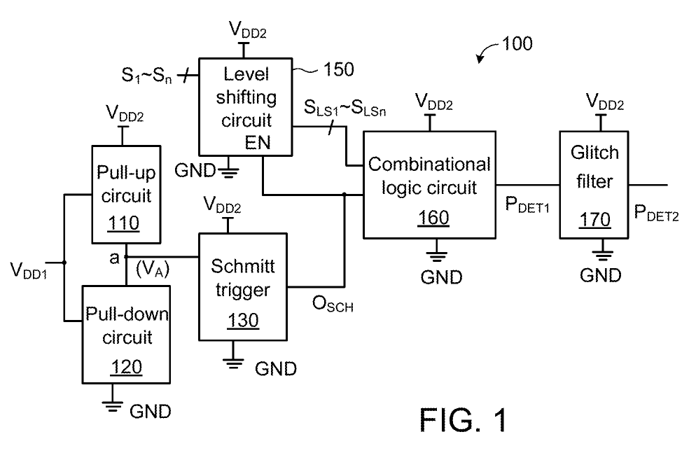

FIG. 1 is a schematic circuit block illustrating the architecture of a power-on detection circuit according to a first embodiment of the present invention. As shown in FIG. 1, the power-on detection circuit 100 includes a pull-up circuit 110, a pull-down circuit 120, a Schmitt trigger 130, a level shifting circuit 150, a combinational logic circuit 160, and a glitch filter 170.

The input terminal of the pull-up circuit 110 and the input terminal of the pull-down circuit 120 receive the supply voltage V_{DD1}. The pull-up circuit 110 is connected between the supply voltage V_{DD2} and the node a. The pull-down circuit 120 is connected between the node a and the ground terminal GND. According to the amplitude of the supply voltage V_{DD1}, the pull-up circuit 110 pulls up the voltage V_{A} of the node a to the supply voltage V_{DD2}, or the pull-down circuit 120 pulls down the voltage V_{A} of the node a to the ground voltage (0V). Generally, the voltage V_{A} of the node a varies between the supply voltage V_{DD2} and the ground voltage (0V). That is, the voltage V_{A} of the node a is a signal belonging to the power domain of V_{DD2}.

The two power terminals of the Schmitt trigger 130 receive the supply voltage V_{DD2} and the ground voltage (0V), respectively. The input terminal of the Schmitt trigger 130 is connected to the node a to receive the voltage V_{A}. The output terminal of the Schmitt trigger 130 generates a Schmitt output signal O_{SCH}. The Schmitt output signal O_{SCH} is a signal belonging to the V_{DD2} power domain.

The enable terminal EN of the level shifting circuit 150 receives the Schmitt output signal O_{SCH}. When the level shifting circuit 150 is enabled, the level shifting circuit 150 converts n input signals S₁~Sₙ into n level-shifted signals S_{LS1}~S_{LSn}. The n input signals S₁~Sₙ belong to the V_{DD1} power domain. The n level-shifted signals S_{LS1}~S_{LSn} belong to the V_{DD2} power domain. Furthermore, n is a positive integer greater than or equal to 1. In other words, in the simplest situation, the level shifting circuit 150 receives a single input signal S₁ and converts the input signal S₁ into the level-shifted signal S_{LS1}.

The combinational logic circuit 160 receives the n level-shifted signals S_{LS1}~S_{LSn} and the Schmitt output signal O_{SCH}, and generates a first power detecting signal P_{DET1}. Furthermore, the glitch filter 170 receives the first power detecting signal P_{DET1}. The glitch filter 170 can filter out the glitches in the first power detecting signal P_{DET1}and generates a second power detecting signal P_{DET}₂. Both the first power detecting signal P_{DET1} and the second power detecting signal P_{DET} belong to the V_{DD2} power domain.

In practice, one of the first power detecting signal P_{DET1} and the second power detecting signal P_{DET2} can use as the output signal of the power-on detection circuit 100. For precise power detection, the first power detecting signal P_{DET1} can be used and the glitch filter 170 can be omitted. This allows detection of any unstable noises on the supply voltage V_{DD1}. For coarse power detection, the glitch filter 170 and the second power detecting signal P_{DET2} can be used. The accuracy of power detection is selectively adjusted using the glitch filter 170 according to actual needs.

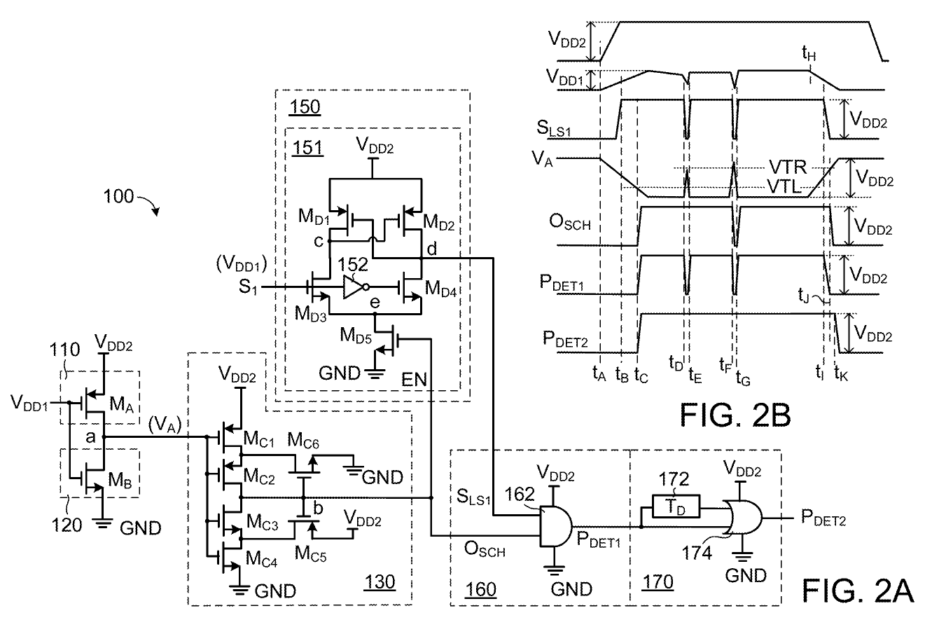

FIG. 2A is a schematic circuit diagram illustrating the detailed circuitry of the power-on detection circuit according to the first embodiment of the present invention. The pull-up circuit 110 includes a pull-up path. The pull-up path includes a transistor M_{A}. The pull-down circuit 120 includes a pull-down path. The pull-down path includes a transistor M_{B}. The source terminal of the transistor M_{A} receives the supply voltage V_{DD2}. The drain terminal of the transistor M_{A} is connected to the node a. The gate terminal of the transistor M_{A} receives the supply voltage V_{DD1}. The drain terminal of the transistor M_{B} is connected to the node a. The source terminal of the transistor M_{B} receives the ground voltage (0V). The gate terminal of the transistor M_{B} receives the supply voltage V_{DD1}. When the supply voltage V_{DD1} is not yet in the normal condition, the pull-up path is turned on, and the pull-down path is turned off, the pull-down capability is smaller than the pull-up capability. Under this circumstance, the voltage V_{A} at the node a is pulled up to the supply voltage V_{DD2} by the pull-up circuit 110. When the supply voltage V_{DD1} is in the normal condition, the pull-up capability is smaller than the pull-down capability. Under this circumstance, the voltage V_{A} at the node a is pulled down to the ground voltage (0V) by the pull-down circuit 120.

The Schmitt trigger 130 includes transistors M_{C1}~M_{C6}. The source terminal of the transistor M_{C1} receives the supply voltage V_{DD2}. The gate terminal of the transistor M_{C1} serves as the input terminal of the Schmitt trigger 130 to receive the voltage V_{A}. The source terminal of the transistor M_{C2} is connected to the drain terminal of the transistor M_{C1}. The gate terminal of the transistor M_{C2} receives the voltage V_{A}. The drain terminal of the transistor M_{C2} is connected to the node b. The drain terminal of the transistor M_{C3} is connected to the node b. The gate terminal of the transistor M_{C3} receives the voltage V_{A}. The drain terminal of the transistor M_{C4} is connected to the source terminal of the transistor M_{C3}. The gate terminal of the transistor M_{C4} receives the voltage VA. The source terminal of the transistor M_{C4} receives the ground voltage (0V). The drain terminal of the transistor M_{C5} is connected to the source terminal of the transistor M_{C3}. The gate terminal of the transistor M_{C5} is connected to the node b. The source terminal of the transistor M_{C5} receives the supply voltage V_{DD2}. The drain terminal of the transistor M_{C6} is connected to the source terminal of the transistor M_{C2}. The gate terminal of the transistor M_{C6} is connected to the node b. The source terminal of the transistor M_{C6} receives the ground voltage (0V). The node b is the output terminal of Schmitt trigger 130 to generate the Schmitt output signal O_{SCH}.

For example, the Schmitt trigger 130 is an inverting Schmitt trigger with a high threshold voltage (VTR) and a low threshold voltage (VTL). In other words, the Schmitt trigger 130 is able to provide hysteresis between the high threshold voltage (VTR) and a low threshold voltage (VTL). When the voltage V_{A} exceeds the high threshold voltage VTR in the rising period, the Schmitt output signal O_{SCH} is changed to the logic low level state, i.e., the ground voltage (0V). When the V_{A} falls below the low threshold voltage VTL in the falling period, the Schmitt output signal O_{SCH} is changed to the logic high level state, i.e., the supply voltage V_{DD2}.

The level shifting circuit 150 includes a single level shifter 151. The level shifter 151 includes transistors M_{D1}~M_{D5} and an inverter 152. The source terminal of the transistor M_{D1} receives the supply voltage V_{DD2}. The gate terminal of the transistor M_{D1} is connected to the node d. The drain terminal of the transistor M_{D1} is connected to the node c. The node d is the output terminal of the level shifter 151 capable of generating the level-shifted signal S_{LS1}. The source terminal of the transistor M_{D2} receives the supply voltage V_{DD2}. The gate terminal of the transistor M_{D2} is connected to the node c. The drain terminal of the transistor M_{D2} is connected to the node d. The drain terminal of the transistor M_{D3} is connected to the node c. The gate terminal of the transistor M_{D3}serves as the input terminal of the level shifter 150 to receive the input signal S₁. The source terminal of the transistor M_{D3} is connected to the node e. The input terminal of the inverter 152 receives the input signal S₁. The drain terminal of the transistor M_{D4} is connected to the node d. The gate terminal of the transistor M_{D4} is connected to the output terminal of inverter 152. The source terminal of the transistor M_{D4} is connected to the node e. The drain terminal of the transistor M_{D}₅ is connected to the node e. The source terminal of the transistor M_{D}₅ receives the ground voltage (0V). The gate terminal of the transistor M_{D}₅ serves as the enable terminal EN of the level shifter 151 and receives the Schmitt output signal O_{SCH}.

For example, the level shifter 151 is a latch-type level shifter. When the Schmitt output signal O_{SCH} is in the logic low level state, the level shifting circuit 150 is disabled, and the level shifter 151 does not operate. When the Schmitt output signal O_{SCH} is in the logic high level state, the level shifting circuit 150 is enabled, and the level shifter 151 operates normally. Consequently, when the input signal S₁ is in the logic high state corresponding to the supply voltage V_{DD1}, the level-shifted signal S_{LS1} is in the logic high level state corresponding to the supply voltage V_{DD2}. When the input signal S₁ is in the logic low level state corresponding to the ground voltage (0V), the level-shifted signal S_{LS1} is also at a logically low level of ground voltage (0V).

The combinational logic circuit 160 includes an AND gate 162. The two power terminals of the AND gate 162 receive the supply voltage V_{DD2} and the ground voltage (0V), respectively. The two input terminals of the AND gate 162 serve as the input terminals of the combinational logic circuit 160 to receive the level-shifted signal S_{LS1} and the Schmitt trigger output signal O_{SCH}, respectively. Furthermore, the output terminal of the AND gate 162 serves as the output terminal of the combinational logic circuit 160 and generates the first power detecting signal P_{DET1}.

The glitch filter 170 includes a delay element 172 and an OR gate 174. The input terminal of the delay element 172 is connected to the output terminal of the combinational logic circuit 160 to receive the first power detecting signal P_{DET1}. Furthermore, the delay element 172 receives the first power detecting signal P_{DET1} and delays the first power detecting signal P_{DET1} by a delay time T_{D}. For example, the delay time T_{D} of the delay element 172 is 10 ns. The two power terminals of the OR gate 174 receive the supply voltage V_{DD2}and the ground voltage (0V), respectively. The two input terminals of the OR gate 174 are connected to the output terminal of the combinational logic circuit 160 and the output terminal of the delay element 172, respectively. The output terminal of the OR gate 174 generates the second power detecting signal P_{DET}₂. Generally, when a glitch occurs on the first power detecting signal P_{DET1} and the glitch period is less than the delay time T_{D}, the glitch can be filtered out.

In this embodiment, the input signal S₁ of the level shifter 151 is a signal in the V_{DD1} power domain. In the following descriptions, the supply voltage V_{DD1} is used as the input signal S₁. The operations of the power-on detection circuit 100 will be described as follows.

FIG. 2B is a schematic timing waveform diagram illustrating associated signals of the power-on detection circuit according to the first embodiment of the present invention.

At the time point t_{A}, the IC chip is powered on, and the supply voltages V_{DD1} and V_{DD2} gradually rise. The pull-up circuit 110 is gradually turned off. The pull-down circuit 120 is gradually turned on.

At the time point t_{B}, the level-shifted signal S_{LS1} is switched to the logic high level state of the supply voltage V_{DD2}.

At the time point t_{C}, the voltage V_{A} drops to the low threshold voltage VTL, and the Schmitt output signal O_{SCH} is switched to the logic high level state of the supply voltage V_{DD2}. Consequently, the first power detecting signal P_{DET1} from the combinational logic circuit 160 is switched from the logic low level state (0V) to the logic high level state (V_{DD2}). The second power detecting signal P_{DET}₂from the glitch filter 170 is the logic high level of the supply voltage V_{DD2}, indicating that the supply voltage V_{DD1} is normal.

In the time interval between the time point t_{D} and the time point t_{E}, the supply voltage V_{DD}₁ becomes unstable and drops slightly, and the voltage V_{A} has not yet exceeded the high threshold voltage VTR. The Schmitt trigger output signal O_{SCH} is maintained in the logic high level state of the supply voltage V_{DD2}. Furthermore, the level-shifted signal S_{LS1} is switched to the logic low level state of the ground voltage (0V). Consequently, a glitch occurs in the first power detecting signal P_{DET1} of the combinational logic circuit 160. This glitch is filtered out by the glitch filter 170. Consequently, the second power detecting signal P_{DET}₂ is in the logic high level state corresponding to the supply voltage V_{DD2}, indicating that the supply voltage V_{DD1} is normal.

Similarly, in the time interval between the time point t_{F} and the time point t_{G}, the supply voltage V_{DD} becomes unstable and drops slightly. Consequently, the voltage V_{A} exceeds the high threshold voltage VTR, and the Schmitt trigger output signal O_{SCH} is in the logic low level state corresponding to the ground voltage (0V). Furthermore, the level-shifted signal S_{LS1} is also in the logic low level state corresponding to the ground voltage (0V). Consequently, a glitch occurs in the first power detecting signal P_{DET1} from the combinational logic circuit 160. Moreover, the glitch is filtered out by the glitch filter 170. Consequently, the second power detecting signal P_{DET}₂is in the logic high level state corresponding to the supply voltage V_{DD2}, indicating that the supply voltage V_{DD1} is normal.

Of course, if the time interval between the time point t_{F} and the time point t_{G} is greater than the delay time T_{D}, the second power detecting signal P_{DET}₂ from the glitch filter 170 will be switched to the logic low level state corresponding to the ground voltage (0V), indicating that the supply voltage V_{DD1} is abnormal.

At the time point t_{H}, the supply voltage V_{DD1} drops. The pull-up circuit 110 is gradually turned on. The pull-down circuit 120 is gradually turned off.

At the time point t_{I}, the level-shifted signal S_{LS1} is in the logic low level state corresponding to the ground voltage (0V). Consequently, the first power detecting signal P_{DET1} from the combinational logic circuit 160 is switched from the logic high level state to the logic low level state corresponding to the ground voltage (0V). At the time point t_{J}, the voltage V_{A} rises to the high threshold voltage VTR, and the Schmitt output signal O_{SCH} is switched from the logic high level state (V_{DD2}) to the logic low level state of the ground voltage (0V).

Furthermore, the time interval between the time point t_{I} and the time point t_{K} is the delay time T_{D}. That is, at the time point t_{K}, the second power detecting signal P_{DET}₂ from the glitch filter 170 is switched to a logic low level state corresponding to the ground voltage (0V), indicating that the supply voltage V_{DD1} is abnormal.

As mentioned above, the power-on detection circuit 100 includes the level shifter 150, the pull-up circuit 110 and the pull-down circuit 120 to convert the signal in the V_{DD1} power domain into the signal in the V_{DD2} power domain. Then, the Schmitt trigger 130, the combinational logic circuit 160 and the glitch filter 170 in the V_{DD2} power domain are used to determine whether the supply voltage V_{DD1} in the V_{DD1} power domain is normal.

It is noted that the actual circuit structures of the level shifting circuit 150, the pull-up circuit 110, the pull-down circuit 120, the Schmitt trigger 130, the combinational logic circuit 160 and the glitch filter 170 are not restricted. That is, the circuitry structures of these components can be modified according to the practical requirements. For example, in a variant example, the pull-up circuit 110 and the pull-down circuit 120 are combined as a level shifter and used in the level shifting circuit 150. Similarly, the Schmitt trigger 130 can also be implemented using a combination of a comparator and a resistor. The glitch filter 170 can be implemented using a combination of an RC circuit and a sequential logic circuit. Furthermore, the pull-up capability of the pull-up circuit 110 and the pull-down capability of the pull-down circuit 120 can be modified according to the practical requirements.

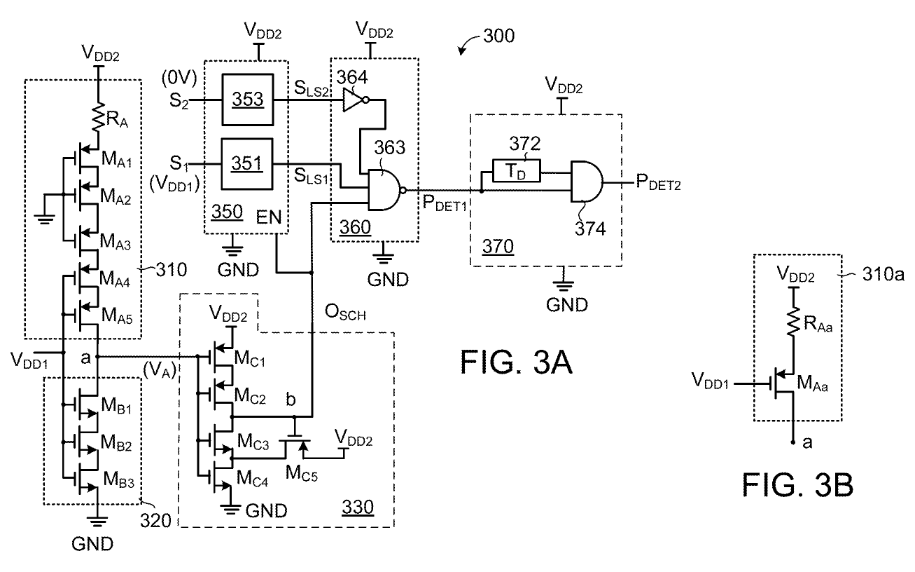

FIG. 3A is a schematic circuit diagram illustrating a variant example of the detailed circuitry of the power-on detection circuit according to the first embodiment of the present invention. As shown in FIG. 3A, the power-on detection circuit 300 includes a pull-up circuit 310, a pull-down circuit 320, a Schmitt trigger 330, a level shifting circuit 350, a combinational logic circuit 360, and a glitch filter 370. The pull-up circuit 310 has a weak pull-up capability, and the pull-down circuit 320 has a weak pull-down capability.

The pull-up circuit 310 includes a pull-up path. The pull-up path includes a resistor R_{A} and transistors M_{A1}~M_{A5}. The first terminal of the resistor R_{A} receives the supply voltage V_{DD2}. The source terminal of the transistor M_{A1} is connected to the second terminal of the resistor R_{A}. The gate terminal of the transistor M_{A1} receives the ground voltage (0V). The source terminal of the transistor M_{A2} is connected to the drain terminal of the transistor M_{A1}. The gate terminal of the transistor M_{A2} receives the ground voltage (0V). The source terminal of the transistor M_{A3} is connected to the drain terminal of the transistor M_{A2}. The gate terminal of the transistor M_{A3} receives the ground voltage (0V). The source terminal of the transistor M_{A4} is connected to the drain terminal of the transistor M_{A3}. The gate terminal of the transistor M_{A4} receives the supply voltage V_{DD1}. The source terminal of the transistor M_{A5} is connected to the drain terminal of the transistor M_{A4}. The gate terminal of the transistor M_{A5} receives the supply voltage V_{DD1}. The drain terminal of the transistor M_{A5} is connected to the node a.

The pull-down circuit 320 includes a pull-down path. The pull-down path includes transistors M_{B1}~M_{B3}. The drain terminal of the transistor M_{B1} is connected to the node a. The gate terminal of the transistor M_{B1} receives the supply voltage V_{DD1}. The drain terminal of the transistor M_{B2} is connected to the source terminal of the transistor M_{B1}. The gate terminal of the transistor M_{B2} receives the supply voltage V_{DD1}. The drain terminal of the transistor M_{B3} is connected to the source terminal of the transistor M_{B2}. The gate terminal of the transistor M_{B3} receives the supply voltage V_{DD1}. The source terminal of the transistor M_{B3} receives the ground voltage (0V).

The level shifting circuit 350 includes two level shifters 351 and 353. The enable terminals of the level shifters 351 and 353 receive the Schmitt output signal O_{SCH}. The input terminal of the level shifter 351 receives an input signal S₁. The output terminal of the level shifter 351 generates a level-shifted signal S_{LS1}. The input terminal of the level shifter 353 receives an input signal S₂. The output terminal of the level shifter 353 generates a level-shifted signal S_{LS2}. The level-shifted signal S_{LS}₁ is at the supply voltage V_{DD2} when the input signal S₁ is at the supply voltage V_{DD1}. The level-shifted signal S_{LS2} is at the ground voltage when the input signal S₂ is at the ground voltage. Generally, the circuitry structure of each of the level shifters 351 and 353 may be identical to the level shifter 151 in FIG. 2A, and not be redundantly described herein.

The Schmitt trigger 330 includes transistors M_{C1}~M_{C5}. When compared with the Schmitt trigger 130 in FIG. 2A, Schmitt trigger 330 of this embodiment is not equipped with the transistor M_{C6}. The Schmitt trigger 330 only causes a change in the level of the high threshold voltage VTR. The operations of the Schmitt trigger 330 are similar. In a variant example of FIG. 2A, the Schmitt trigger 130 is modified. For example, the Schmitt trigger 130 is not equipped with the transistor M_{C5}, but the transistor M_{C6} is retained. This will cause a change in the level of the low threshold voltage VTL.

In some embodiments, when the supply voltage V_{DD1} is normal, the second power detecting signal P_{DET}₂ may be in the logic low level state. The combinational logic circuit 360 includes a NAND gate 363 and a NOT gate 364. The two power terminals of the NAND gate 363 and NOT gate 364 receive the supply voltage V_{DD2} and the ground voltage (0V), respectively. The input terminal of the NOT gate 364 receives the level-shifted signal S_{LS2}. The first input terminal of the NAND gate 363 is connected to the output terminal of the NOT gate 364. The second input terminal of the NAND gate 363 receives the level-shifted signal S_{LS1}. The third input terminal of the NAND gate 363 receives the Schmitt output signal O_{SCH}. Furthermore, the output terminal of the NAND gate 363 generates the first power detecting signal P_{DET1}.

The glitch filter 370 includes a delay element 372 and an AND gate 374. The input terminal of the delay element 372 is connected to the output terminal of the combinational logic circuit 360 to receive the first power detecting signal P_{DET1}. Furthermore, the delay element 372 receives the first power detecting signal P_{DET1} and delays the first power detecting signal P_{DET1} by a delay time T_{D}. The two power terminals of the AND gate 374 receive the supply voltage V_{DD2} and the ground voltage (0V), respectively. The two input terminals of AND gate 374 are connected to the output terminal of combinational logic circuit 360 and the output terminal of delay element 372, respectively. The output terminal of AND gate 374 generates a second power detecting signal P_{DET}₂. Similarly, the glitch filter 370 can also be selectively used or removed depending on actual needs.

Generally, the operations of the power-on detection circuit 300 in FIG. 3 are similar to those of the power-on detection circuit 100 in FIG. 2A. For example, the input signal S₁ is the supply voltage V_{DD1}, and the input signal S₂ is the ground voltage (0V). After the IC chip is powered on, the two level shifters 351 and 353 will be operated normally. Meanwhile, the three input terminals of the NAND gate 363 in the combinational logic circuit 360 are all in the logic high level state corresponding to the supply voltage V_{DD2}, and the first power detecting signal P_{DET1} is in the logic low level state corresponding to the ground voltage (0V). Consequently, the second power detecting signal P_{DET}₂ is in the logic low level state corresponding to the ground voltage (0V), indicating that the supply voltage V_{DD1} is normal.

On the other hand, when the supply voltage V_{DD1} is unstable, the second power detecting signal P_{DET}₂ of the power-on detection circuit 300 will be switched to the logic high level state corresponding to the supply voltage V_{DD2}, indicating that the supply voltage V_{DD1} is abnormal.

It is noted that the number of transistors in the pull-up circuit 310 and the number of transistors in the pull-down circuit 320 can be appropriately increased or decreased according to the practical requirements. Alternatively, the pull-up circuit 310 is equipped with the transistors M_{A1}~M_{A5}, but is not equipped with the resistor R_{A}.

For example, another example of the pull-up circuit is shown in FIG. 3B. The pull-up circuit 310a includes a resistor R_{Aa} and a transistor M_{Aa}. The first terminal of the resistor R_{Aa} receives the supply voltage V_{DD2}. The source terminal of the transistor M_{Aa} is connected to the second terminal of the resistor R_{A}ₐ. The gate terminal of the transistor M_{Aa} receives the supply voltage V_{DD1}. The drain terminal of the transistor M_{Aa} is connected to the node a.

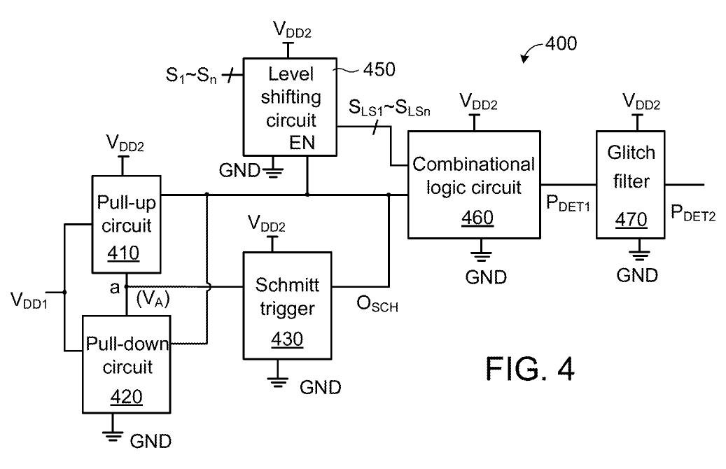

FIG. 4 is a schematic circuit block illustrating the architecture of a power-on detection circuit according to a second embodiment of the present invention. As shown in FIG. 4, the power-on detection circuit 400 includes a pull-up circuit 410, a pull-down circuit 420, a Schmitt trigger 430, a level shifting circuit 450, a combinational logic circuit 460, and a glitch filter 470.

When compared with the power-on detection circuit 100 in the first embodiment, the Schmitt output signal O_{SCH} in the power-on detection circuit 400 of the second embodiment is transmitted to the pull-up circuit 410 to adjust the pull-up capability of the pull-up circuit 410 and reduce the power consumption of the pull-up circuit 410. Similarly, the Schmitt output signal O_{SCH} is transmitted to the pull-down circuit 420 to adjust its pull-down capability. For brevity, only the pull-up circuit 410 and the pull-down circuit 420 in the second embodiment will be described as follows. The other circuits in the power-on detection circuit 400 of the second embodiment can be referred to the first embodiment and will not be redundantly described herein.

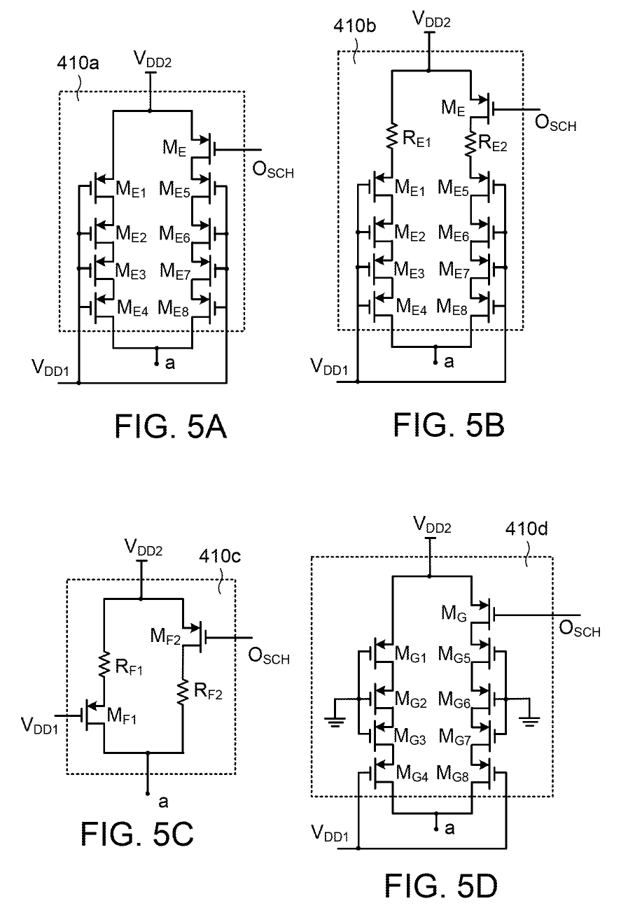

FIG. 5A is a schematic circuit diagram illustrating a first example of the pull-up circuit used in the power-on detection circuit of the second embodiment. FIG. 5B is a schematic circuit diagram illustrating a second example of the pull-up circuit used in the power-on detection circuit of the second embodiment. FIG. 5C is a schematic circuit diagram illustrating a third example of the pull-up circuit used in the power-on detection circuit of the second embodiment. FIG. 5D is a schematic circuit diagram illustrating a fourth example of the pull-up circuit used in the power-on detection circuit of the second embodiment.

As shown in FIG. 5A, the pull-up circuit 410a includes two pull-up paths. The first pull-up path is controlled according to the supply voltage V_{DD1}. The first pull-up path includes transistors M_{E1}~M_{E4}. The second pull-up path is controlled according to the supply voltage V_{DD1} and the Schmitt output signal O_{SCH}. The second pull-up path includes transistors M_{E} and M_{E5}~M_{E8}.

In the first pull-up path, the source terminal of the transistor M_{E1} is coupled to the supply voltage V_{DD2}, and the gate terminal of the transistor M_{E1} receives the supply voltage V_{DD1}. The source terminal of the transistor M_{E2} is connected to the drain terminal of the transistor M_{E1}, and the gate terminal of the transistor M_{E2} receives the supply voltage V_{DD1}. The source terminal of the transistor M_{E3} is connected to the drain terminal of the transistor M_{E2}, and the gate terminal of the transistor M_{E3} receives the supply voltage V_{DD1}. The source terminal of the transistor M_{E4} is connected to the drain terminal of the transistor M_{E3}, the gate terminal of the transistor M_{E4} receives the supply voltage V_{DD1}, and the drain terminal of the transistor M_{E4} is connected to the node a.

In the second pull-up path, the source terminal of the transistor M_{E} is coupled to the supply voltage V_{DD2}, and the gate terminal of the transistor M_{E} receives the Schmitt output signal O_{SCH}. The source terminal of the transistor M_{E5} is connected to the drain terminal of the transistor M_{E}, and the gate terminal of the transistor M_{E5} receives the supply voltage V_{DD1}. The source terminal of the transistor M_{E6} is connected to the drain terminal of the transistor M_{E5}, and the gate terminal of the transistor M_{E6} receives the supply voltage V_{DD1}. The source terminal of the transistor M_{E7} is connected to the drain terminal of the transistor M_{E6}, and the gate terminal of the transistor M_{E7} receives the supply voltage V_{DD1}. The source terminal of the transistor M_{E8} is connected to the drain terminal of the transistor M_{E7}, the gate terminal of the transistor M_{E8} receives the supply voltage V_{DD1}, and the drain terminal of the transistor M_{E8} is connected to the node a.

Generally, when the Schmitt output signal O_{SCH} is the ground voltage (0V), the second pull-up path is turned on, and the pull-up circuit 410a has the stronger pull-up capability. When the Schmitt output signal O_{SCH} is the supply voltage V_{DD2}, the second pull-up path is turned off, and the pull-up circuit 410a has the weaker pull-up capability. Furthermore, the number of the transistors in the two pull-up paths can be adjusted appropriately.

As shown in FIG. 5B, the pull-up circuit 410b includes two pull-up paths. The first pull-up path is controlled according to the supply voltage V_{DD1}. The first pull-up path includes a resistor R_{E1} and transistors M_{E1}~M_{E4}. The second pull-up path is controlled according to the supply voltage V_{DD1} and the Schmitt output signal O_{SCH}. The second pull-up path includes a resistor R_{E2} and transistors M_{E} and M_{E5}~M_{E8}.

When compared with the pull-up circuit 410a in FIG. 5A, the pull-up circuit 410b in FIG. 5B is additionally equipped with resistors R_{E1} and R_{E2}. The resistor R_{E1} is connected between the supply voltage V_{DD2} and the source terminal of the transistor M_{E1}. The resistor R_{E2} is connected between the source terminal of the transistor M_{E}₅ and the drain terminal of the transistor M_{E}. That is, the source terminal of the transistor M_{E1} is coupled to the supply voltage V_{DD2} through the resistor R_{E1}, and the source terminal of the transistor M_{E}₅ is coupled to the drain terminal of the transistor M_{E} through the resistor R_{E2}. The operations of the pull-up circuit 410b in FIG. 5B are similar to the operations of the pull-up circuit 410a in FIG. 5A and not redundantly described herein. Similarly, the number of the transistors in the two pull-up paths can be adjusted appropriately.

As shown in FIG. 5C, the pull-up circuit 410c includes two pull-up paths. The first pull-up path is controlled according to the supply voltage V_{DD1}. The first pull-up path includes a resistor R_{F1} and a transistor M_{F1}. The second pull-up path is controlled according to the Schmitt output signal O_{SCH}. The second pull-up path includes a resistor R_{F2} and a transistor M_{F2}.

In the first pull-up path, the first terminal of the resistor R_{F1} receives the supply voltage V_{DD2}, the source terminal of the transistor M_{F1} is connected to the second terminal of the resistor R_{F1}, the gate terminal of the transistor M_{F1} receives the supply voltage V_{DD1}, and the drain terminal of the transistor M_{F1} is connected to the node a.

In the second pull-up path, the first terminal of the resistor R_{F2} receives the supply voltage V_{DD2}, the source terminal of the transistor M_{F2} is connected to the second terminal of the resistor R_{F2}, the gate terminal of the transistor M_{F2} receives the Schmitt output signal O_{SCH}, and the drain terminal of the transistor M_{F2} is connected to the node a.

The operations of the pull-up circuit 410c in FIG. 5C are similar to the operations of the pull-up circuit 410a in FIG. 5A and not redundantly described herein.

As shown in FIG. 5D, the pull-up circuit 410d includes two pull-up paths. The first pull-up path is controlled according to the supply voltage V_{DD1}. The first pull-up path includes transistors M_{G1}~M_{G4}. The second pull-up path is controlled according to the supply voltage V_{DD1} and the Schmitt output signal O_{SCH}. The second pull-up path includes transistors M_{G} and M_{G5}~M_{G8}.

In the first pull-up path, the source terminal of the transistor M_{G1} is connected to the supply voltage V_{DD2}, and the gate terminal of the transistor M_{G1} receives the ground voltage (0V). The source terminal of the transistor M_{G2} is connected to the drain terminal of the transistor M_{G1}, and the gate terminal of the transistor M_{G2} receives the ground voltage (0V). The source terminal of the transistor M_{G3} is connected to the drain terminal of the transistor M_{G2}, and the gate terminal of the transistor M_{G3} receives the ground voltage (0V). The source terminal of the transistor M_{G4} is connected to the drain terminal of the transistor M_{G3}, the gate terminal of the transistor M_{G4} receives the supply voltage V_{DD1}, and the drain terminal of the transistor M_{G4} is connected to the node a.

In the second pull-up path, the transistor M_{G} is connected to the supply voltage V_{DD2}, and the gate terminal of the transistor M_{G} receives the Schmitt output signal O_{SCH}. The source terminal of the transistor M_{G5} is connected to the drain terminal of the transistor M_{G}, and the gate terminal of the transistor M_{G5} receives the ground voltage (0V). The source terminal of the transistor M_{G6} is connected to the drain terminal of the transistor M_{G5}, and the gate terminal of the transistor M_{G6}receives the ground voltage (0V). The source terminal of the transistor M_{G7} is connected to the drain terminal of the transistor M_{G6}, and the gate terminal of the transistor M_{G7}receives the ground voltage (0V). The source terminal of the transistor M_{G8} is connected to the drain terminal of the transistor M_{G7}, the gate terminal of the transistor M_{G8} receives the supply voltage V_{DD1}, and the drain terminal of the transistor M_{G8} is connected to the node a.

The operations of the pull-up circuit 410d in FIG. 5D are similar to the operations of the pull-up circuit 410a in FIG. 5A and not redundantly described herein. Similarly, the number of the transistors in the two pull-up paths can be adjusted appropriately.

FIG. 5E is a schematic circuit diagram illustrating a first example of the pull-down circuit used in the power-on detection circuit of the second embodiment. FIG. 5F is a schematic circuit diagram illustrating a second example of the pull-down circuit used in the power-on detection circuit of the second embodiment.

As shown in FIG. 5E, the pull-down circuit 420a includes two pull-down paths. The first pull-down path is controlled according to the supply voltage V_{DD1}. The first pull-down path includes transistors M_{H1}~M_{H3}. The second pull-down path is controlled according to the Schmitt output signal O_{SCH}. The second pull-down path includes transistors M_{H4}~M_{H6}.

In the first pull-down path, the drain terminal of the transistor M_{H1} is connected to the node a, and the gate terminal of the transistor M_{H1} receives the supply voltage V_{DD1}. The drain terminal of the transistor M_{H2} is connected to the source terminal of the transistor M_{H1}, and the gate terminal of the transistor M_{H2} receives the supply voltage V_{DD1}. The drain terminal of the transistor M_{H3} is connected to the source terminal of the transistor M_{H2}, the gate terminal of the transistor M_{H3} receives the supply voltage V_{DD1}, and the source terminal of the transistor M_{H}₃ receives the ground voltage (0V).

In the second pull-down path, the drain terminal of the transistor M_{H4} is connected to the node a, and the gate terminal of the transistor M_{H4} receives the Schmitt output signal O_{SCH}. The drain terminal of the transistor M_{H5} is connected to the source terminal of the transistor M_{H4}, and the gate terminal of the transistor M_{H5} receives the Schmitt output signal O_{SCH}. The drain terminal of the transistor M_{H6} is connected to the source terminal of the transistor M_{H5}, the gate terminal of the transistor M_{H}₆ receives the Schmitt output signal O_{SCH}, and the source terminal of the transistor M_{H6} receives the ground voltage (0V).

Generally, when the Schmitt output signal O_{SCH} is the ground voltage (0V), the second pull-down path is turned off, and the pull-down circuit 420a has the weak pull-down capability. When the Schmitt output signal O_{SCH} is the supply voltage V_{DD2}, the second pull-down path is turned on, and the pull-down circuit 420a has the stronger pull-down capability. Furthermore, the number of the transistors in the two pull-down paths can be adjusted appropriately.

As shown in FIG. 5F, the pull-down circuit 420b includes two pull-down paths. The first pull-down path is controlled according to the supply voltage V_{DD1}. The first pull-down path includes transistors M_{I1}~M_{I3}. The second pull-down path is controlled according to the supply voltage V_{DD1} and the Schmitt output signal O_{SCH}. The second pull-down path includes transistors M_{I4}~M_{I6}.

In the first pull-down path, the drain terminal of the transistor M_{I1} is connected to the node a, and the gate terminal of the transistor M_{I1} receives the supply voltage V_{DD1}. The drain terminal of the transistor M_{I2} is connected to the source terminal of the transistor M_{I1}, and the gate terminal of the transistor M_{I2} receives the supply voltage V_{DD1}. The drain terminal of the transistor M_{I3} is connected to the source terminal of the transistor M_{I2}, the gate terminal of the transistor M_{I3} receives the supply voltage V_{DD1}, and the source terminal of the transistor M_{I}₃ receives the ground voltage (0V).

In the second pull-down path, the drain terminal of the transistor M_{I4} is connected to the node a, and the gate terminal of the transistor M_{I4} receives the Schmitt output signal O_{SCH}. The drain terminal of the transistor M_{I5} is connected to the source terminal of the transistor M_{I4}, and the gate terminal of the transistor M_{I5} receives the supply voltage V_{DD1}. The drain terminal of the transistor M_{I6} is connected to the source terminal of the transistor M_{I5}, the gate terminal of the transistor M_{I}₆ receives the supply voltage V_{DD1}, and the source terminal of the transistor M_{I6} receives the ground voltage (0V).

The operations of the pull-down circuit 420b in FIG. 5F are similar to the operations of the pull-down circuit 420a in FIG. 5E and not redundantly described herein. Similarly, the number of the transistors in the two pull-down paths can be adjusted appropriately.

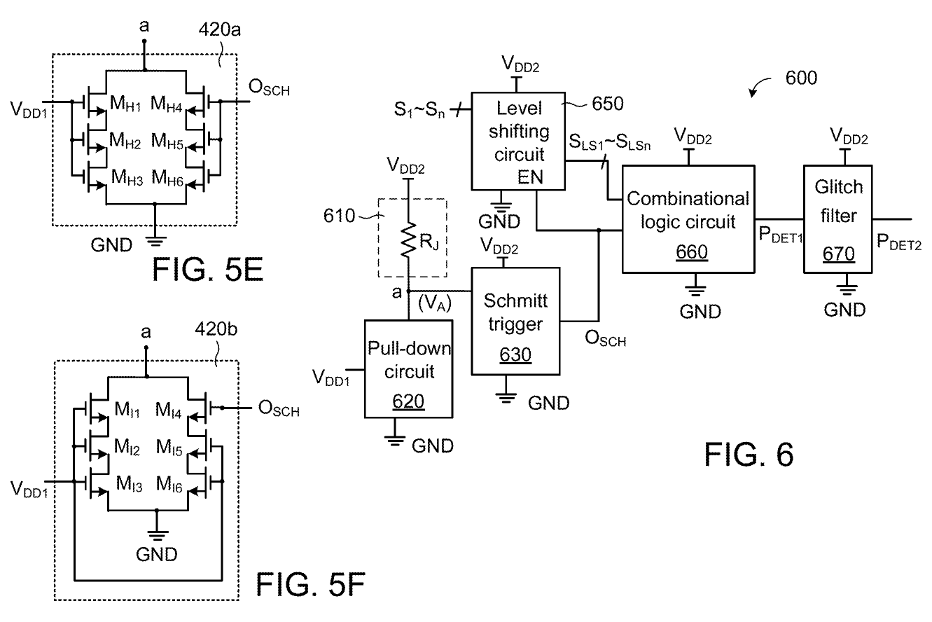

FIG. 6 is a schematic circuit block illustrating the architecture of a power-on detection circuit according to a third embodiment of the present invention. As shown in FIG. 6, the power-on detection circuit 600 includes a pull-up circuit 610, a pull-down circuit 620, a Schmitt trigger 630, a level shifting circuit 650, a combinational logic circuit 660, and a glitch filter 670.

When compared with the power-on detection circuit 100 of the first embodiment, the pull-up circuit 610 in the power-on detection circuit 600 of the third embodiment does not receive the supply voltage V_{DD1}. The other circuits in the power-on detection circuit 600 of the third embodiment can be referred to the first embodiment and will not be redundantly described herein.

In this embodiment, the pull-up circuit 610 is an always-on pull-up path, which has the weak pull-up capability. For example, the pull-up circuit 610 includes a resistor R_{J}. The resistor R_{J} is connected between the supply voltage V_{DD2} and the node a. The resistance value of the resistor R_{J} is in the range between several hundred kilohms and several megohms.

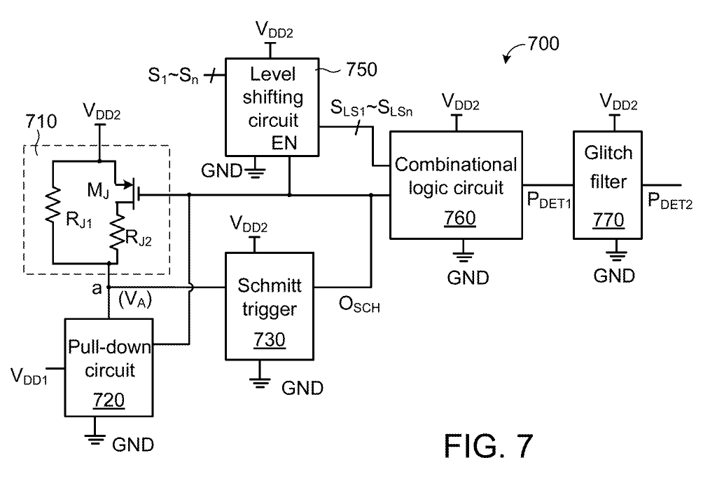

FIG. 7 is a schematic circuit block illustrating the architecture of a power-on detection circuit according to a fourth embodiment of the present invention. As shown in FIG. 7, the power-on detection circuit 700 includes a pull-up circuit 710, a pull-down circuit 720, a Schmitt trigger 730, a level shifting circuit 750, a combinational logic circuit 760, and a glitch filter 770.

When compared with the power-on detection circuit 400 of the second embodiment, the pull-up circuit 710 in the power-on detection circuit 700 of the fourth embodiment does not receive the supply voltage V_{DD1}. The other circuits in the power-on detection circuit 700 of the fourth embodiment can be referred to the second embodiment and will not be redundantly described herein.

In this embodiment, the pull-up circuit 710 includes two pull-up paths. The first pull-up path includes a resistor R_{J1}. The second pull-up path includes a resistor R_{J2} and a transistor M_{J}.

In the first pull-up path, the resistor R_{J1} is connected between the supply voltage V_{DD2} and the node a. In the second pull-up path, the source terminal of the transistor M_{J} receives the supply voltage V_{DD2}, the gate terminal of the transistor M_{J} receives the Schmitt output signal O_{SCH}, and the drain terminal of the transistor M_{J} is connected to the resistor R_{J2}.

Generally, when the Schmitt output signal O_{SCH} is the ground voltage (0V), the second pull-up path is turned on, and the pull-up circuit 710 has the stronger pull-up capability. When the Schmitt output signal O_{SCH} is the supply voltage V_{DD2}, the second pull-up path is turned off, and the pull-up circuit 710 has the weaker pull-up capability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power-on detection circuit receiving a first supply voltage in a first power domain and a second supply voltage in a second power domain, the power-on detection circuit comprising:
a pull-up circuit connected between the second supply voltage and a first node;
a pull-down circuit receiving the first supply voltage, wherein the pull-down circuit is connected between the first node and a ground voltage;
a Schmitt trigger connected to the first node, configured to provide hysteresis between a high threshold voltage and a low threshold voltage, wherein the Schmitt trigger generates a Schmitt output signal according to a voltage at the first node;
a level shifting circuit, wherein an enable terminal of the level shifting circuit receives the Schmitt output signal, a first input terminal of the level shifting circuit receives a first input signal, and an output terminal of the level shifting circuit generates a first level-shifted signal at the second supply voltage when the first input signal is at the first supply voltage; and
a combinational logic circuit receiving the first level-shifted signal and the Schmitt output signal, and configured to generate a first power detecting signal in a predetermined logic level state when the Schmitt output signal and the first level-shifted signal are at the second supply voltage;
wherein the first input signal is a signal belonging to the first power domain,
wherein the voltage at the first node, the first level-shifted signal, the Schmitt output signal, the first power detecting signal are signals belonging to the second power domain.

2. The power-on detection circuit as claimed in claim 1, wherein the second supply voltage is greater than the first supply voltage.

3. The power-on detection circuit as claimed in claim 1, wherein the Schmitt trigger comprises:
a first transistor, wherein a source terminal of the first transistor receives the second supply voltage, and a gate terminal of the first transistor is connected to the first node;
a second transistor, wherein a source terminal of the second transistor is connected to a drain terminal of the first transistor, a gate terminal of the second transistor is connected to the first node, and a drain terminal of the second transistor connected to a second node;
a third transistor, wherein a drain terminal of the third transistor is connected to the second node, and a gate terminal of the third transistor is connected to the first node;
a fourth transistor, wherein a drain terminal of the fourth transistor is connected to a source terminal of the third transistor, a gate terminal of the fourth transistor is connected to the first node, and a source terminal of the fourth transistor receives the ground voltage; and
a fifth transistor, wherein a drain terminal of the fifth transistor is connected to a source terminal of the third transistor, a gate terminal of the fifth transistor is connected to the second node, and a source terminal of the fifth transistor receives the second supply voltage.

4. The power-on detection circuit as claimed in claim 1, wherein the pull-up circuit comprises a first pull-up path and a second pull-up path, and the second pull-up path is controlled according to the Schmitt output signal.

5. The power-on detection circuit as claimed in claim 1, wherein the pull-down circuit comprises a first pull-down path and a second pull-down path, wherein the first pull-down path is controlled according to the first supply voltage, and the second pull-down path is controlled according to the Schmitt output signal.

6. The power-on detection circuit as claimed in claim 1, wherein the pull-up circuit receives the first supply voltage, wherein according to an amplitude of the first supply voltage, the voltage at the first node is pulled up to the second supply voltage by the pull-up circuit, or the voltage at the first node is pulled down to the ground voltage by the pull-down circuit.

7. The power-on detection circuit as claimed in claim 6, wherein the pull-up circuit comprises a pull-up path, and the pull-up path comprises:
a resistor, wherein a first terminal of the resistor receives the second supply voltage;
a first transistor, wherein a source terminal of the first transistor is connected to a second terminal of the resistor, and a gate terminal of the first transistor receives the ground voltage;
a second transistor, wherein a source terminal of the second transistor is connected to a drain terminal of the first transistor, and a gate terminal of the second transistor receives the ground voltage;
a third transistor, wherein a source terminal of the third transistor is connected to a drain terminal of the second transistor, and a gate terminal of the third transistor receives the ground voltage;
a fourth transistor, wherein a source terminal of the fourth transistor is connected to a drain terminal of the third transistor, and a gate terminal of the fourth transistor receives the first supply voltage; and
a fifth transistor, wherein a source terminal of the fifth transistor is connected to a drain terminal of the fourth transistor, a gate terminal of the fifth transistor receives the first supply voltage, and a drain terminal of the fifth transistor is connected to the first node.

8. The power-on detection circuit as claimed in claim 6, wherein the pull-down circuit comprises a pull-down path, and the pull-down path comprises:
a first transistor, wherein a drain terminal of the first transistor is connected to the first node, and a gate terminal of the first transistor receives the first supply voltage;
a second transistor, wherein a drain terminal of the second transistor is connected to a source terminal of the first transistor, and a gate terminal of the second transistor receives the first supply voltage; and
a third transistor, wherein a drain terminal of the third transistor is connected to a source terminal of the second transistor, a gate terminal of the third transistor receives the first supply voltage, and a source terminal of the third transistor receives the ground voltage.

9. The power-on detection circuit as claimed in claim 1, wherein the level shifting circuit comprises a first level shifter, wherein an enable terminal of the first level shifter receives the Schmitt output signal, an input terminal of the first level shifter receives the first input signal, and an output terminal of the first level shifter generates the first level-shifted signal.

10. The power-on detection circuit as claimed in claim 9, wherein the level shifting circuit further comprises a second level shifter, wherein an enable terminal of the second level shifter receives the Schmitt output signal, an input terminal of the second level shifter receives a second input signal, and an output terminal of the second level shifter generates a second level-shifted signal.

11. The power-on detection circuit as claimed in claim 10, wherein the first input signal is the first supply voltage, and the second input signal is the ground voltage.

12. The power-on detection circuit as claimed in claim 11, wherein the combinational logic circuit receives the first level-shifted signal, the second level-shifted signal and the Schmitt output signal, and the combinational logic circuit generates the first power detecting signal in the predetermined logic level state when the first level-shifted signal and the Schmitt output signal are at the second supply voltage, and the second level-shifted signal is at the ground voltage.

13. The power-on detection circuit as claimed in claim 1, further comprises a glitch filter capable of receiving the first power detecting signal and generating a second power detecting signal, wherein a glitch on the first power detecting signal is filtered out by the glitch filter.

14. The power-on detection circuit as claimed in claim 13, the glitch filter comprises a delay element having a predetermined delay time, and is configured to filter out a glitch when the glitch occurs on the first power detecting signal and a duration of the glitch is shorter than the delay time.

15. The power-on detection circuit as claimed in claim 13, wherein the second power detecting signal in a first logical level state indicates that the first supply voltage is normal, and the second power detecting signal in a second logical level state indicates that the first supply voltage is abnormal.

16. The power-on detection circuit as claimed in claim 1, wherein the pull-up circuit and the pull-down circuit receives the Schmitt output signal, and a pull-up capability of the pull-up circuit and a pull-down capability of the pull-down circuit are controlled according to the Schmitt output signal.

17. The power-on detection circuit as claimed in claim 16, wherein the pull-up circuit comprises a first pull-up path and a second pull-up path, wherein the first pull-up path is controlled according to the first supply voltage, and the second pull-up path is controlled according to the Schmitt output signal.

18. The power-on detection circuit as claimed in claim 16, wherein the pull-down circuit comprises a first pull-down path and a second pull-down path, wherein the first pull-down path is controlled according to the first supply voltage, and the second pull-down path is controlled according to the Schmitt output signal.
*****
